(19) United States
(12) Patent Application Publication
(10) Pub. No.: US 2019/0302551 A1
(43) Pub. Date: Oct. 3, 2019

(54) ARRAY SUBSTRATE AND MANUFACTURING METHOD OF ARRAY SUBSTRATE

(71) Applicant: SHENZHEN CHINA STAR OPTOELECTRONICS SEMICONDUCTOR DISPLAY TECHNOLOGY CO., LTD., Shenzhen (CN)

(72) Inventor: Wu CAO, Shenzhen (CN)

(21) Appl. No.: 16/040,655

(22) Filed: Jul. 20, 2018

Related U.S. Application Data
(63) Continuation of application No. PCT/CN2018/084032, filed on Apr. 23, 2018.

(30) Foreign Application Priority Data
Mar. 30, 2018 (CN) 201810294128.1

(51) Int. Cl. G02F 1/1362; H01L 27/12

(52) U.S. Cl. CPC G02F 1/136227; H01L 27/1244; G02F 2001/136222; H01L 27/1288; H01L 27/1248

(57) ABSTRACT

The present disclosure relates to an array substrate. The array substrate includes a component layer and a covering layer disposed on the component layer. The covering layer includes at least one through hole, and at least two lateral sides of the at least one through hole have different declination angles with respect to a horizontal plane. A pixel electrode is formed on the covering layer, and the pixel electrode of the covering layer is connected to a source or a drain of the component layer via the at least one through hole.

### CROSS REFERENCE TO RELATED APPLICATIONS

This application is a continuing application of PCT Patent Application No. PCT/CN2018/084032, entitled “ARRAY SUBSTRATE AND MANUFACTURING METHOD OF ARRAY SUBSTRATE”, filed on Apr. 23, 2018, which claims priority to Chinese Patent Application No. 201810294128.1, filed on Mar. 30, 2018, both of which are hereby incorporated in its entireties by reference.

### BACKGROUND

### 1. Technical Field

The present disclosure generally relates to display technology field, and especially relates to an array substrate and a manufacturing method of an array substrate.

### 2. Description of Related Art

Referring to FIG. 1. A color filter on array (COA) is a structure that a color filter (CF) 2 is formed on an array substrate. The structure can effectively reduce the light leakage problem due to misalignment, and decrease the coupling capacitor between the signal lines and the pixel electrodes 5, so as to effectively increase the aperture ratio of the pixel electrode. Therefore, the structure is wildly applied in the liquid crystal display field.

The inventors of the present disclosure understands that, in an array substrate of a conventional COA substrate, it needs to have a through hole in high thickness of the color filter (CF) layer 2 or a passivation layer (as shown in FIG. 1, a through hole in CF layer 2. Have a through hole 3, so as to expose a source or a drain 4, and then form a pixel electrode 5 on the CF layer 2 or the passivation layer. The pixel electrode 3 is connected to the source or the drain 4 via the through hole 3, the through hole 3 on the CF layer 2 or the passivation layer includes declination angles β that are the same in two lateral side of the cross-sectional diagram (Take an upper surface of the CF layer 2 as a horizontal plane). That is, the declination angles β is a symmetric structure. Due that the thickness of the CF layer 2 or the passivation layer is higher (if the thickness of the passivation layer is small, the declination angle β of the through hole has small effect, not shown in FIG. 2). When the declination angle β is too large such that the terrain is not smooth. The photoresist of the pixel electrode 5 in the exposure of the pattern process is stacked along the edge, resulting in exposing non-sufficiently, such that the pixel electrode 5 is easily exist after etching and removing the photoresist. The residue of the pixel electrode 5 is short-connection with other electrodes, such that the pixel electrode 5 cannot be charged, that is, the pixel electrode cannot be turned on, or the electrical property is changed, resulting in display quality problem like insufficient charge and color shift.

### SUMMARY

The present disclosure relates to an array substrate and a manufacturing method of an array substrate, so as to avoid the residue of a pixel electrode that results in the short-connection of the electrodes to cause the problem of product quality.

In one aspect, an array substrate is provided. The array substrate includes a component layer and a covering layer disposed on the component layer. The covering layer includes at least one through hole, and at least two lateral sides of the at least one through hole have different declination angles with respect to a horizontal plane. A pixel electrode is formed on the covering layer, and the pixel electrode of the covering layer is connected to a source or a drain of the component layer via the at least one through hole. The covering layer is a stripe-shaped color resist layer, and the at least one through hole passes through the stripe-shaped color resist layer and the covering layer. The declination angles with respect to the horizontal plane include at least a first declination angle and a second declination angle, respectively. The first declination angle is larger than the second declination angle, and the pixel electrode extends through a first lateral side of the at least one through hole and arrives the horizontal plane, and the first lateral side corresponds to the first declination angle, and the second declination angle corresponds to another lateral side of the at least through hole.

In another aspect, an array substrate is provided. The array substrate includes a component layer and a covering layer disposed on the component layer. The covering layer includes at least one through hole, and at least two lateral sides of the at least one through hole have different declination angles with respect to a horizontal plane. A pixel electrode is formed on the covering layer, and the pixel electrode of the covering layer is connected to a source or a drain of the component layer via the at least one through hole.

In another aspect, a manufacturing method of an array substrate is provided. The method includes: forming a component layer; forming a covering layer disposed on the component layer; the covering layer including at least one through hole, at least two lateral sides of the at least one through hole having different declination angles with respect to a horizontal plane; and forming a pixel electrode disposed on the covering layer; wherein the pixel electrode is connected to a source or a drain of the component layer via the at least one through hole.

In view of the above, the present disclosure uses an array substrate. The array substrate includes a component layer and a covering layer disposed on the component layer. The covering layer includes at least one through hole, and at least two lateral sides of the at least one through hole have different declination angles with respect to a horizontal plane. A pixel electrode is formed on the covering layer, and the pixel electrode of the covering layer is connected to a source or a drain of the component layer via the at least one through hole, By the array substrate above, the residue of a pixel electrode that results in the short-connection of the electrodes, causing the problem of product quality, can be avoided.

### BRIEF DESCRIPTION OF THE DRAWINGS

FIG. 1 is a schematic diagram of a conventional COA substrate.

FIG. 2 is a cross-sectional diagram of the conventional COA substrate.

FIG. 3 is a schematic diagram of an array substrate in accordance with one embodiment of the present disclosure.

FIG. 4 is a schematic diagram of an array substrate in accordance with another embodiment of the present disclosure.

FIG. 5 is a cross-sectional diagram of the array substrate in accordance with one embodiment of the present disclosure.

FIGS. 6a and 6b area schematic diagram of two measuring methods of an declination angle of the through hole in accordance with one embodiment of the present disclosure.

FIG. 7 is a schematic diagram of the array substrate in which the electrodes are short-connection in accordance with one embodiment of the present disclosure.

FIG. 8 is a schematic diagram of the array substrate in which the electrodes are short-connection in accordance with another embodiment of the present disclosure.

FIG. 9 is a schematic diagram of a liquid crystal display in accordance with one embodiment of the present disclosure.

FIG. 10 is a schematic diagram of a manufacturing method of an array substrate in accordance with one embodiment of the present disclosure.

FIG. 11 is a schematic diagram of a layout of the through hole of the manufacturing method of the array substrate in accordance with one embodiment of the present disclosure.

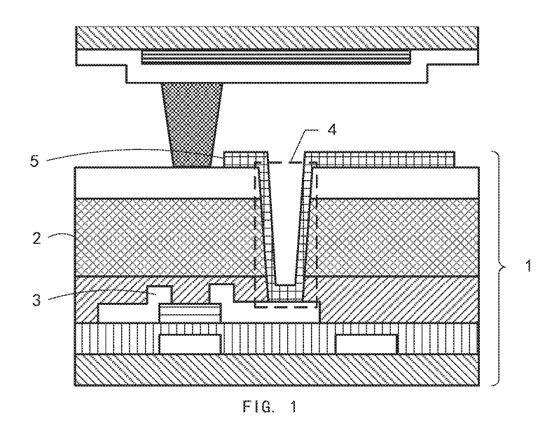

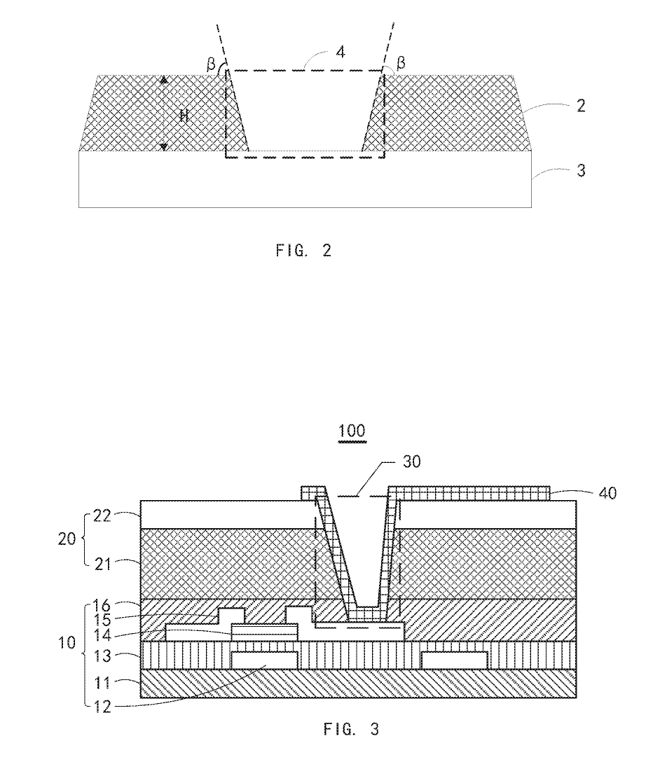

### DETAILED DESCRIPTION

Following embodiments of the invention will now be described in detail hereinafter with reference to the accompanying drawings.

In the drawings, the thicknesses of layers and regions may be exaggerated for clarity. Same reference numerals refer to the same components throughout the specification and the drawings.

The above description is merely the embodiments in the present disclosure, the claim is not limited to the description thereby. The equivalent structure or changing of the process of the content of the description and the figures, or to implement to other technical field directly or indirectly should be included in the claim.

Referring to FIG. 3, FIG. 3 is a schematic diagram of an array substrate in accordance with one embodiment of the present disclosure. The array substrate includes a component layer 10 and a covering layer 20 disposed on the component layer 10. The covering layer 20 includes at least one through hole 30. At least two lateral sides of the through hole 30 have different declination angles θ with respect to a horizontal plane. At least one pixel electrode 40 is formed on the covering layer 20. The pixel electrode 40 of the covering layer 20 is connected to a source or a drain 15 of the component layer 10 via the through hole 30.

Specifically, as shown in FIG. 3, the covering layer 20 is a stripe-shaped color resist layer 21 and a second passivation layer 22 on the stripe-shaped color resist layer 21. The through hole 30 passes through the stripe-shaped color resist layer 21 and the second passivation layer 22. That is, the through hole 30 passes through the covering layer 20.

The horizontal plane is a surface parallel to a surface of the covering layer 20 or a surface of the component layer 10.

The component layer 10 includes, sequentially, a first substrate 11, a gate 12, an insulating layer 13, an active layer 14, a source or drain 15 and a first passivation layer 16. The stripe-shaped color resist layer 21 is disposed between the first passivation layer 16 and the second passivation layer 22.

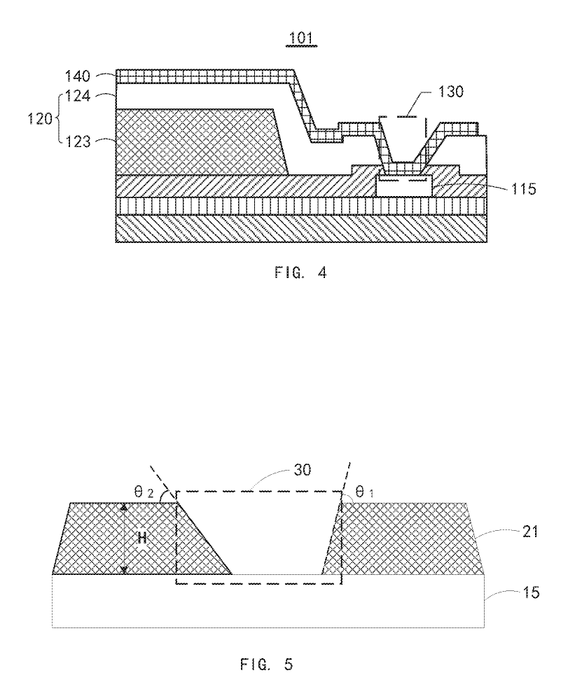

As shown in FIG. 4, FIG. 4 is a schematic diagram of an array substrate in accordance with another embodiment of the present disclosure. The difference between the array substrate 101 of FIG. 4 and the array substrate 100 of FIG. 3 is that a covering layer 120 of FIG. 4 includes an island-shaped color resist layer 123 and a flat layer 124 disposed on the island-shaped color resist layer 123. The through hole 130 passes through the covering layer 120. That is, the through hole 130 passes through the flat layer 124. The pixel electrode 140 is connected to a source or drain 115 via the through hole 130.

Referring to FIG. 5, FIG. 5 is a cross-sectional diagram of a through hole of an array substrate in accordance with one embodiment of the present disclosure. The through hole 30 is an anti-symmetric structure. The declination angles θ of at least two lateral sides of the through hole 30 with respect to the horizontal plane, that is an upper surface of the covering layer 20, are a first declination angle and a second declination angle, respectively. In the embodiment, take the first declination angle θ₁ and the second declination angle θ₂ that are formed as two corresponding lateral sides of the through hole 30 with respect to the upper surface of the covering layer 20 as the horizontal plane as an example. The first declination angle θ₁ is larger than the second declination angle θ₂. The pixel electrode 40 extends through a first lateral side of the through hole 30 and arrives the horizontal plane, and the first lateral side corresponds to the first declination angle θ₁, and the second declination angle θ₂ corresponds to another lateral side of the through hole 30.

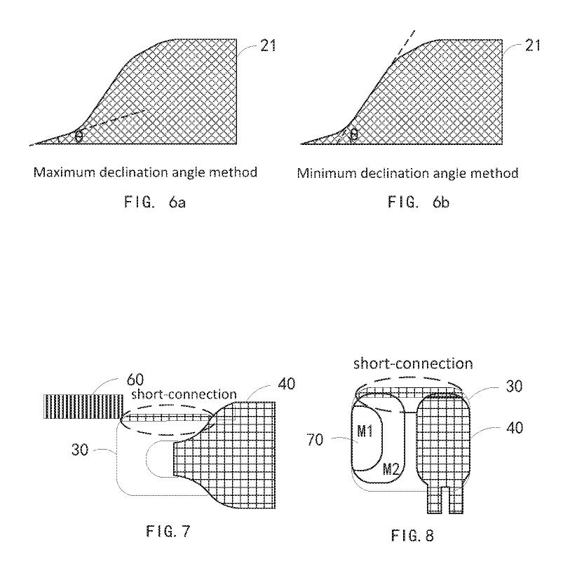

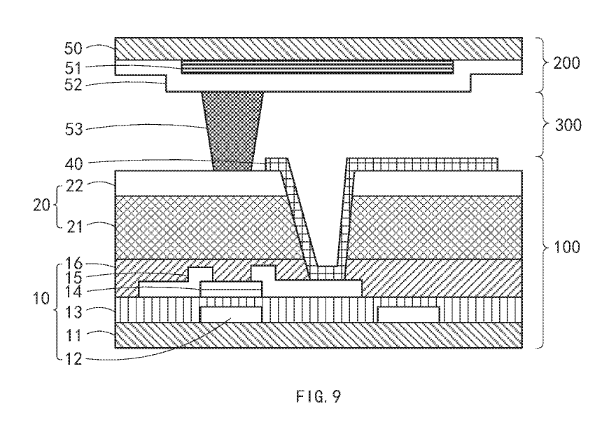

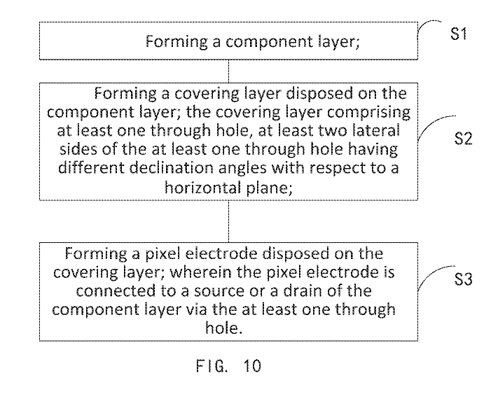

FIGS. 6a and 6b area schematic diagram of two measuring methods of an declination angle of the through hole in accordance with one embodiment of the present disclosure. The results between two measuring methods are different. Take the bottom surface of the covering surface 20 as the horizontal plane, and the measurement for the maximum declination of the lateral side of the through hole is the method for the maximum value (as shown in FIG. 6b), and the result is the declination angle θ.

Specifically, a difference between the first declination angle θ₁ and the second declination angle θ₂ is larger than or equal to 10 degrees, and the first declination angle θ₁ and the second declination angle θ₂ are in a range from 30 to 80 degrees.

In another embodiment, an ITO common electrode 60 (taking the through hole 30 only for the pixel electrode 40 as an example) being configured on the same layer with the pixel electrode 40 is disposed outside the lateral side of the through hole 30 corresponding to the second declination angle θ₂. By the through hole 30 (anti-symmetric structure) of the present disclosure, expose and pattern the pixel electrode 40 on the through hole 30, and etch the pixel electrode 40 on the lateral side of the through hole 30 corresponding to the second declination angle θ₂, such that the pixel electrode 40 extends through a first lateral side of the through hole 30 and arrives the horizontal plane, and the pixel electrode 40 is connected to the source or the drain 15 via the through hole 30. Due that the first declination angle θ₁ is larger than the second declination angle θ₂, that is, the second declination angle θ₂ is smaller, when exposing the pixel electrode 40 corresponding the second declination angle θ₂ of the lateral side of the through hole 30, the etching glue is not easily residual on the area between the pixel electrode 40 and the common electrode 60 corresponding to the second declination angle θ₂ of the lateral side of the through hole 30, resulting in the remain of the pixel electrode 40 on the lateral side of the through hole 30, such that the area of the pixel electrode 40 can be exposed sufficiently, and the pixel electrode 40 is not residual after etching and removing the glue, avoiding the stacking of the etching glue on the lateral side of the pixel electrode 40 because the second declination angle θ₂ is larger, resulting in the residue of the pixel electrode 40 because of not sufficient exposure, such that the short-connection as shown in FIG. 7 (top view) is happening between the residue of the pixel electrode 40 and the ITO common electrode 60 configured on the same layer with the pixel electrode 40 disposed outside the lateral side of the through hole 30 corresponding to the second declination angle θ₂.

In another embodiment, a transfer electrode 70 (taking electrodes inside the through hole 30) formed by two metal layers M1 and M2 configured on the same layer with the pixel electrode 40 is disposed inside the lateral side of the through hole 30 corresponding to the second declination angle θ₂. By the through hole 30 (anti-symmetric structure) of the present disclosure, based on the above reason, and the description is omit herein, avoiding the stacking of the etching glue on the lateral side of the pixel electrode 40 because the second declination angle θ₂ is larger, resulting in the residue of the pixel electrode 40 because of not sufficient exposure, such that the short-connection as shown in FIG. 8 (top view) is happening between the residue of the pixel electrode 40 and the ITO common electrode 60 configured on the same layer with the pixel electrode 40 disposed outside the lateral side of the through hole 30 corresponding to the second declination angle θ₂.

Referring to FIG. 10, FIG. 10 is a schematic diagram of a manufacturing method of an array substrate in accordance with one embodiment of the present disclosure. The manufacturing method of the array substrate will be described in accompanying with FIG. 3. The method includes step S1 forming a component layer 10.

A first substrate 11 is provided. A metal film layer is deposited on the first substrate 11. By exposing the metal film layer via a mask, the metal film layer is etched to form a gate 12. An insulating layer 13 is formed on the gate 12 and the first substrate 11 being not covered by the gate 12. An active layer 14 is formed on the insulating layer 13 above the gate 12. A metal layer is further deposited on the active layer 14. After a source and a drain 15 is patterned within the active area, the part of the metal layer outside the pattern of the source and the drain 15 in the active area is etched. The source and the drain 15 are formed on the insulating layer 13, and the source and the drain 14 are respectively connected to the ends of the active layer 14. The metal layer corresponding to the channel is etched to expose the part of the channel. A first passivation layer 16 is formed on the source and the drain 15 to cover the source and the drain 15, the insulating layer 13, and the active layer 14.

Step S2: forming a covering layer 20 disposed on the component layer 10; the covering layer 20 including at least one through hole 30, at least two lateral sides of the through hole 30 having different declination angles θ with respect to a horizontal plane.

Wherein, in the embodiment, the declination angles θ of the two lateral sides of the through hole 30 with respect to the horizontal plane, that is a surface parallel to a surface of the covering layer 20 or a surface of the component layer 10, are a first declination angle θ₁ and a second declination angle θ₂, respectively. The first declination angle θ₁ is larger than the second declination angle θ₂. A difference between the first declination angle θ₁ and the second declination angle θ₂ is larger than or equal to 10 degrees, and the first declination angle θ₁ and the second declination angle θ₂ are in a range from 30 to 80 degrees. The pixel electrode 40 extends through a first lateral side of the through hole 30 and arrives the horizontal plane, and the first lateral side corresponds to the first declination angle θ₁, and the second declination angle corresponds to another lateral side of the through hole 30.

In the embodiment, the covering layer 20 is a stripe-shaped color resist layer 21 and a second passivation layer 22 on the stripe-shaped color resist layer 21. The through hole 30 passes through the stripe-shaped color resist layer 21 and the second passivation layer 22, such that the source and the drain 15 are exposed. In another embodiment, as shown in FIG. 4, the covering layer 120 includes an island-shaped color resist layer 123 and a flat layer 124 disposed on the island-shaped color resist layer 123. The through hole 30 passes through the flat layer 124, such that the source or the drain 115 is exposed.

In the embodiment, expose by a half-tone mask the covering layer 20, such that different declination angles θ in at least two lateral sides of the through hole 30 with respect to the horizontal plane are formed within the covering layer 20.

In another embodiment, expose by a mask with slits the covering layer 20, such that different declination angles θ in at least two lateral sides of the through hole 30 with respect to the horizontal plane are formed within the covering layer 20, or the through hole 30 is formed via other methods.

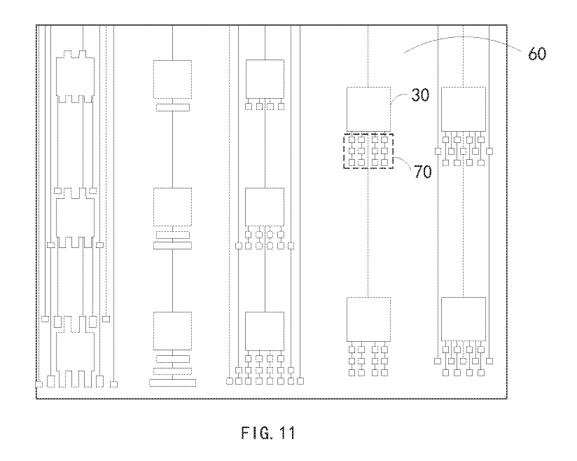

As shown in FIG. 11, by small pattern design with/without light transmission, (CF film area 40 is with light transmission, and the through hole 30 and the special pattern design area 70 is without light transmission), the amount of light transmission can be adjusted in the exposure process, so as to decrease the amount of the exposure of the through hole 30 and the special pattern design area 70, reducing the thickness of the film, forming the side of the small declination angle, so as to form the through hole 30 (anti-symmetric structure) of the present disclosure.

Step S3: forming at least one pixel electrode 40 disposed on the covering layer 20; wherein the pixel electrode 40 is connected to a source or a drain 15 of the component layer 10 via the through hole 30.

In the embodiments of the present disclosure, materials for the first substrate 11, the gate 12, the insulating layer 13, the active layer 14, the source and the drain 15, the first passivation layer 16, the stripe-shaped color resist layer 21, the second passivation layer 22, the island-shaped color resist layer 123, the flat layer 124, the pixel electrode 40, the second substrate 50, the black matrix layer 51, the common electrode layer 52, the light-sensing spacer 53, and the liquid crystal layer 300 between the array substrate 100 and the common electrode 200 are the common materials for person skilled in the art, and the arrangement is common use in the field, and the invention is not limited to this.

The present disclosure uses an array substrate. The array substrate includes a component layer and a covering layer disposed on the component layer. The covering layer includes at least one through hole, and at least two lateral sides of the at least one through hole have different declination angles with respect to a horizontal plane. A pixel electrode is formed on the covering layer, and the pixel electrode of the covering layer is connected to a source or a drain of the component layer via the at least one through hole. By the array substrate above, the residue of a pixel electrode that results in the short-connection of the electrodes, causing the problem of product quality, can be avoided.

For the skilled in the art, it is clear that the disclosure is not limited to the details of an exemplary embodiment. And without departing from the spirit or essential characteristics of the present disclosure, it is possible to realize the disclosure with other specific forms. Therefore, no matter with any points, it should be seen as an exemplary embodiment, but not limiting, the scope of the present disclosure is defined by the appended claims rather than the foregoing description define, and therefore intended to fall claim All changes which come within the meaning and range of equivalents of the elements to include in the present invention.

1. An array substrate, comprising:
a component layer and a covering layer disposed on the component layer;
the covering layer comprising at least one through hole, at least two lateral sides of the at least one through hole having different declination angles with respect to a horizontal plane;
wherein a pixel electrode is formed on the covering layer, the pixel electrode of the covering layer is connected to a source or a drain of the component layer via the at least one through hole;
wherein the covering layer is a stripe-shaped color resist layer, and the at least one through hole passes through the stripe color resist layer and the covering layer; and
wherein the declination angles with respect to the horizontal plane comprises at least a first declination angle and a second declination angle the first declination angle is larger than the second declination angle, the pixel electrode extends through a first lateral side of the at least one through hole and arrives the horizontal plane, and the first lateral side corresponds to the first declination angle, and the second declination angle corresponds to another lateral side of the at least through hole.

2. An array substrate, comprising:
a component layer and a covering layer disposed on the component layer;
the covering layer comprising at least one through hole, at least two lateral sides of the at least one through hole having different declination angles with respect to a horizontal plane;
wherein a pixel electrode is formed on the covering layer, the pixel electrode of the covering layer is connected to a source or a drain of the component layer via the at least one through hole.

3. The array substrate as claimed in claim 2, wherein the covering layer is a stripe-shaped color resist layer, and the at least one through hole passes through the stripe-shaped color resist layer and the covering layer.

4. The array substrate as claimed in claim 2, wherein the covering layer comprises an island-shaped color resist layer and a flat layer disposed on the island-shaped color resist layer, and the at least one through hole passes through the island-shape color resist layer and the flat layer.

5. The array substrate as claimed in claim 2, wherein the declination angles with respect to the horizontal plane comprises at least a first declination angle and a second declination angle, respectively, the first declination angle is larger than the second declination angle, the pixel electrode extends through a first lateral side of the at least one through hole and arrives the horizontal plane, and the first lateral side corresponds to the first declination angle, and the second declination angle corresponds to another lateral side of the at least through hole.

6. The array substrate as claimed in claim 5, wherein a difference between the first declination angle and the second declination angle is larger than or equal to 10 degrees, and the first declination angle and the second declination angle are in a range from 30 to 80 degrees.

7. The array substrate as claimed in claim 5, wherein an electrode being configured on the same layer with the pixel electrode is disposed outside the lateral side of the at least one through hole corresponding to the second declination angle.

8. The array substrate as claimed in claim 5, wherein an electrode being configured on the same layer with the pixel electrode is disposed inside the lateral side of the at least one through hole corresponding to the second declination angle.

9. A manufacturing method of an array substrate, comprising:
forming a component layer;
forming a covering layer disposed on the component layer; the covering layer comprising at least one through hole, at least two lateral sides of the at least one through hole having different declination angles with respect to a horizontal plane; and
forming a pixel electrode disposed on the covering layer; wherein the pixel electrode is connected to a source or a drain of the component layer via the at least one through hole.

10. The method as claimed in claim 9, wherein the declination angles with respect to the horizontal plane comprises at least a first declination angle and a second declination angle, respectively, the first declination angle is larger than the second declination angle, the pixel electrode extends through a first lateral side of the at least one through hole and arrives the horizontal plane, and the first lateral side corresponds to the first declination angle, and the second declination angle corresponds to another lateral side of the at least through hole; and
wherein the step of forming a covering layer disposed on the component layer; the covering layer comprising at least one through hole further comprises:
exposing by a half-tone mask the covering layer, the declination angles in at least two lateral sides of the at least one through hole with respect to the horizontal plane being formed within the covering layer.

11. The method as claimed in claim 9, wherein the declination angles with respect to the horizontal plane comprises at least a first declination angle and a second declination angle, respectively, the first declination angle is larger than the second declination angle, the pixel electrode extends through a first lateral side of the at least one through hole and arrives the horizontal plane, and the first lateral side corresponds to the first declination angle, and the second declination angle corresponds to another lateral side of the at least through hole; and
wherein the step of forming a covering layer disposed on the component layer; the covering layer comprising at least one through hole further comprises:
exposing by a mask with slits the covering layer, the declination angles in at least two lateral sides of the at least one through hole with respect to the horizontal plane being formed within the covering layer.
